(19) United States
(12) Patent Application Publication
(10) Pub. No.: US 2010/0102291 A1
(43) Pub. Date: Apr. 29, 2010

(54) CARBON-BASED MEMORY ELEMENTS EXHIBITING REDUCED DELAMINATION AND METHODS OF FORMING THE SAME

(75) Inventor: Huiwen Xu, Sunnyvale, CA (US)

Correspondence Address: DUGAN & DUGAN, PC, 245 Saw Mill River Road, Suite 309, Hawthorne, NY, 10532, US

(73) Assignee: SanDisk 3D LLC, Milpitas, CA (US)

(21) Appl. No.: 12/604,178

(22) Filed: Oct. 22, 2009

Related U.S. Application Data
(60) Provisional application No. 61/108,017, filed on Oct. 23, 2008.

(51) Int. Cl. H01L 45/00; H01L 21/28

(52) U.S. Cl. 257/4; 438/381; 257/E45.002; 257/E21.158

(57) ABSTRACT

A method of forming a reversible resistance-switching metal-insulator-metal (“MIM”) stack is provided, the method including forming a first conducting layer comprising a degenerately doped semiconductor material, and forming a carbon-based reversible resistance-switching material above the first conducting layer. Other aspects are also provided.

### CROSS-REFERENCE TO RELATED APPLICATIONS

This application claims the benefit of U.S. Provisional Patent Application Ser. No. 61/108,017, filed Oct. 23, 2008, and titled “Methods And Apparatus Exhibiting Reduced Delamination Of Carbon-Based Resistivity-Switching Materials,” (Docket No. SD-MXA-336P), which is incorporated by reference herein in its entirety for all purposes.

### TECHNICAL FIELD

This invention relates to non-volatile memories, and more particularly to carbon-based memory elements exhibiting reduced delamination, and methods of forming the same.

### BACKGROUND

Non-volatile memories formed from reversible resistance switching elements are known. For example, U.S. patent application Ser. No. 11/968,154, filed Dec. 31, 2007, and titled “Memory Cell That Employs A Selectively Fabricated Carbon Nano-Tube Reversible Resistance Switching Element And Methods Of Forming The Same,” (the “'154 Application”) (Docket No. SD-MXA-241), which is incorporated by reference herein in its entirety for all purposes, describes a rewriteable non-volatile memory cell that includes a diode coupled in series with a carbon-based reversible resistivity switching material.

However, fabricating memory devices from carbon-based materials is technically challenging, and improved methods of forming memory devices that employ carbon-based materials are desirable.

### SUMMARY

In a first aspect of the invention, a method of forming a reversible resistance-switching metal-insulator-metal (“MIM”) stack is provided, the method including forming a first conducting layer comprising a degenerately doped semiconductor material, and forming a carbon-based reversible resistance-switching material above the first conducting layer.

In a second aspect of the invention, a method of forming a reversible resistance-switching MIM stack is provided, the method including forming a first conducting layer comprising a silicide, and forming a carbon-based reversible resistance-switching material above the first conducting layer, wherein the first conducting layer and the carbon-based reversible resistance-switching material are formed in the same processing chamber.

In a third aspect of the invention, a method of forming a memory cell is provided, the method including forming a first conducting layer comprising a degenerately doped semiconductor material, forming a carbon-based reversible resistance-switching material above the first conducting layer, and forming a second conducting layer above the carbon-based reversible resistance-switching material.

In a fourth aspect of the invention, a method of forming a memory cell is provided, the method including forming a first conducting layer comprising a silicide, forming a carbon-based reversible resistance-switching material above the first conducting layer, wherein the first conducting layer and the carbon-based reversible resistance-switching material are formed in the same processing chamber, and forming a second conducting layer above the carbon-based reversible resistance-switching material.

In a fifth aspect of the invention, a memory cell is provided, the memory cell including a first conducting layer comprising a degenerately doped semiconductor material, a carbon-based reversible resistance-switching material above the first conducting layer, and a second conducting layer above the carbon-based reversible resistance-switching material.

Other features and aspects of the present invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an exemplary memory cell in accordance with this invention;

FIG. 2A is a simplified perspective view of an exemplary memory cell in accordance with this invention;

FIG. 2B is a simplified perspective view of a portion of a first exemplary memory level formed from a plurality of the memory cells of FIG. 2A;

FIG. 2C is a simplified perspective view of a portion of a first exemplary three-dimensional memory array in accordance with this invention;

FIG. 2D is a simplified perspective view of a portion of a second exemplary three-dimensional memory array in accordance with this invention;

FIGS. 3A-3D illustrate cross-sectional views of exemplary embodiments of memory cells in accordance with this invention; and

FIGS. 4A-4H illustrate cross-sectional views of a portion of a substrate during an exemplary fabrication of a single memory level in accordance with this invention.

### DETAILED DESCRIPTION

Carbon films such as amorphous carbon (“aC”) containing nanocrystalline graphene (referred to herein as “graphitic carbon”), graphene, graphite, carbon nano-tubes, amorphous diamond-like carbon (“DLC”), silicon carbide, boron carbide and other similar carbon-based materials may exhibit resistivity-switching behavior that may make such materials suitable for use in microelectronic non-volatile memories. Indeed, some carbon-based materials have demonstrated reversible resistivity-switching memory properties on lab-scale devices with a 100× separation between ON and OFF states and mid-to-high range resistance changes. Such a separation between ON and OFF states renders carbon-based materials viable candidates for memory cells formed using the carbon materials in memory elements. As used herein, DLC is a carbon material that tends to have primarily tetrahedral carbon-carbon single bonds (often called sp³-bonds), and tends to be amorphous with respect to long range order.

A carbon-based memory element may be formed by arranging a carbon-based resistivity-switching material between bottom and top electrodes to form a MIM structure. In such a configuration, the carbon-based resistivity-switching material sandwiched between the two metal or otherwise conducting layers serves as a carbon-based reversible resistance-switching element. A memory cell may then be formed by coupling the MIM structure in series with a steering element, such as a diode, tunnel junction, thin film transistor, or the like.

In a conventionally-formed MIM structure, the top and bottom electrodes may be formed from a titanium nitride (“TiN”), tantalum nitride (“TaN”), tungsten nitride (“WN”), molybdenum (“Mo”), or other similar material. In some instances, such MIM structures have exhibited failure as a result of the carbon material delaminating or peeling away from TiN bottom electrode layers during use. Research suggests that the delamination/peeling is a result of excessive stress due to the difference in thermal expansion coefficients between the carbon material and TiN, and weak interface adhesion between carbon material and TiN. For example, in an experiment in which a 400 angstrom carbon material layer was formed on a 1200 angstrom TiN sheet film by a plasma-enhanced chemical vapor deposition (“PECVD”) process at 550° C., a thermal induced tensile stress in the carbon element was measured at about 2 GPa.

In accordance with embodiments of the invention, a carbon-based MIM structure is formed that is less prone to carbon layer delamination and/or peeling from the bottom electrode. In one exemplary embodiment, a carbon-based MIM structure is formed in which the bottom electrode is fabricated as a relatively thin, degenerately doped (very highly doped) layer of semiconductor material (e.g., silicon, germanium, a silicon-germanium alloy, or other similar semiconductor material). In a second exemplary embodiment, a carbon-based MIM structure is formed in which the bottom electrode is fabricated as a layer of a conductive silicide (e.g., titanium silicide “TiSi,” tantalum silicide “TaSi,” tungsten silicide “WSi,” copper silicide “CuSi,” or other similar silicide) material. The conductive silicide bottom electrode may be formed by physical vapor deposition (“PVD”), PECVD, or other similar method. In a third exemplary embodiment, a carbon-based MIM structure is formed in which the bottom electrode has a reduced volume and/or reduced interface area between the bottom electrode and the carbon material.

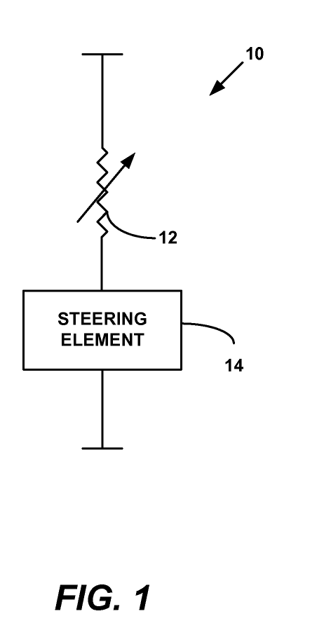

These and other embodiments of the invention are described further below with reference to FIGS. 1-4H.

### Exemplary Inventive Memory Cell

FIG. 1 is a schematic illustration of an exemplary memory cell 10 in accordance with this invention. Memory cell 10 includes a carbon-based reversible resistance-switching element 12 coupled to a steering element 14. Carbon-based reversible resistance-switching reversible resistance switching element 12 includes a carbon-based reversible resistivity switching material (not separately shown) having a resistivity that may be reversibly switched between two or more states.

For example, carbon-based reversible resistance-switching material of element 12 may be in an initial, low-resistivity state upon fabrication. Upon application of a first voltage and/or current, the material is switchable to a high-resistivity state. Application of a second voltage and/or current may return reversible resistivity switching material to a low-resistivity state. Alternatively, carbon-based reversible resistance-switching element 12 may be in an initial, high-resistance state upon fabrication that is reversibly switchable to a low-resistance state upon application of the appropriate voltage(s) and/or current(s). When used in a memory cell, one resistance state may represent a binary “0,” whereas another resistance state may represent a binary “1,” although more than two data/resistance states may be used. Numerous reversible resistivity switching materials and operation of memory cells employing reversible resistance switching elements are described, for example, in U.S. patent application Ser. No. 11/125,939, filed May 9, 2005, and titled “Rewriteable Memory Cell Comprising A Diode And A Resistance Switching Material,” (the “'939 Application”) (Docket No. SD-MA-146), which is incorporated by reference herein in its entirety for all purposes.

Steering element 14 may include a thin film transistor, a diode, metal-insulator-metal tunneling current device, or another similar steering element that exhibits non-ohmic conduction by selectively limiting the voltage across and/or the current flow through carbon-based reversible resistance-switching element 12. In this manner, memory cell 10 may be used as part of a two or three dimensional memory array and data may be written to and/or read from memory cell 10 without affecting the state of other memory cells in the array.

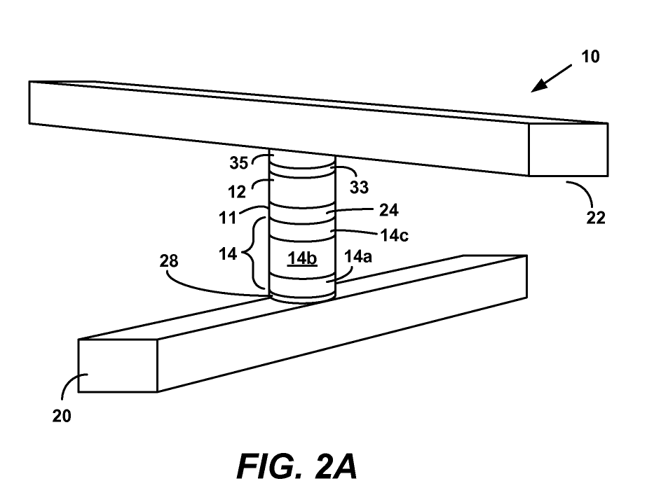

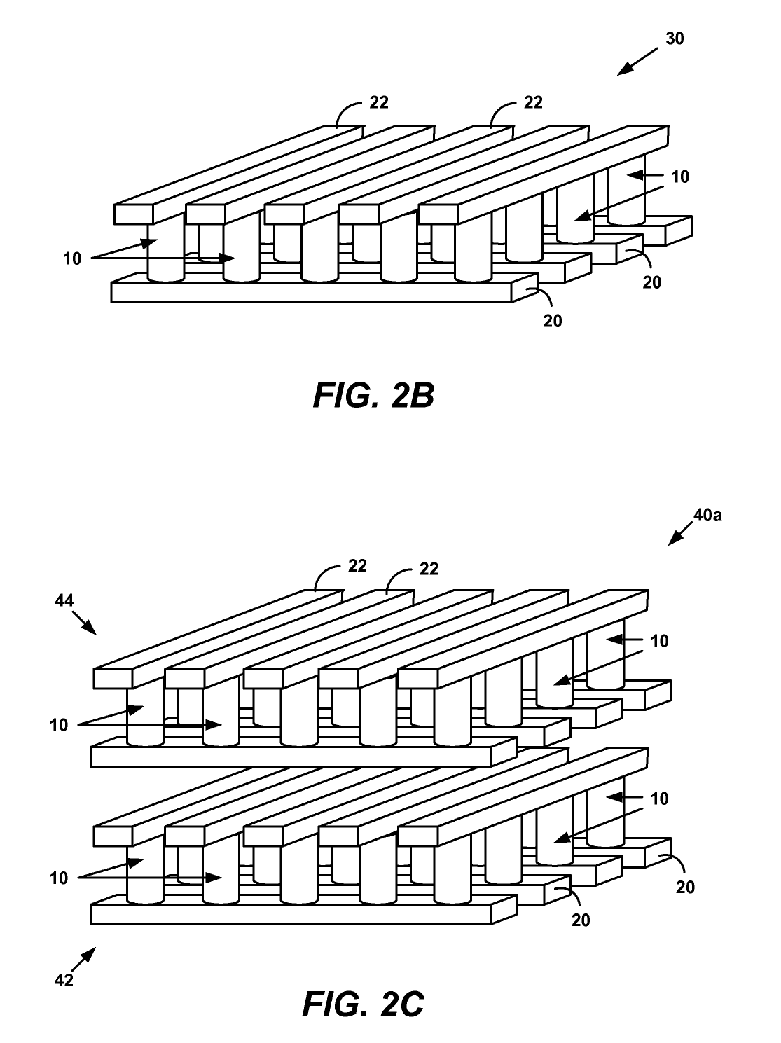

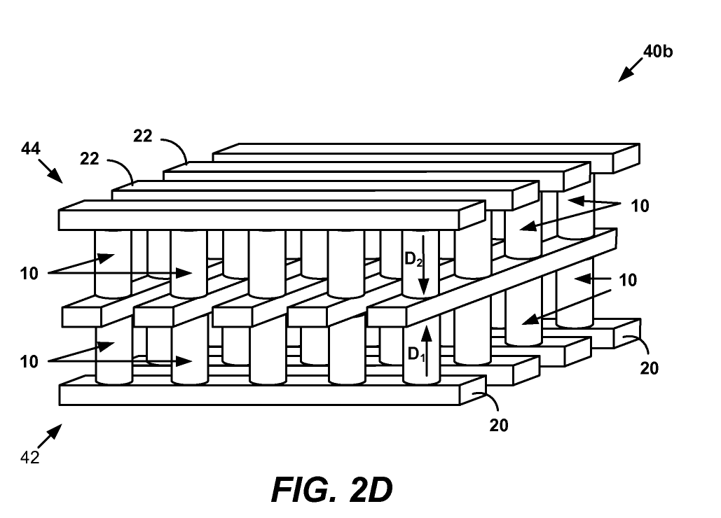

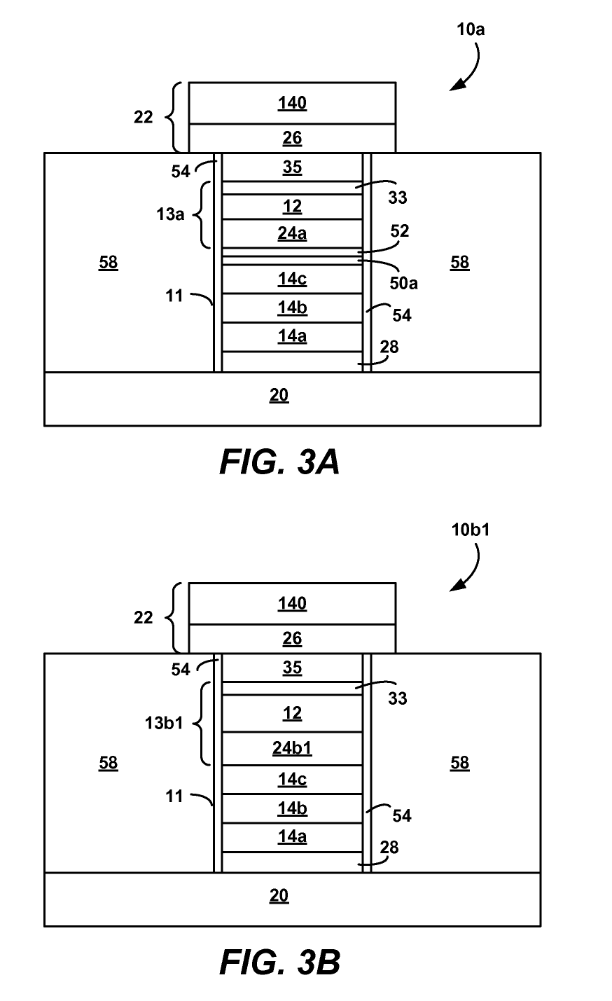

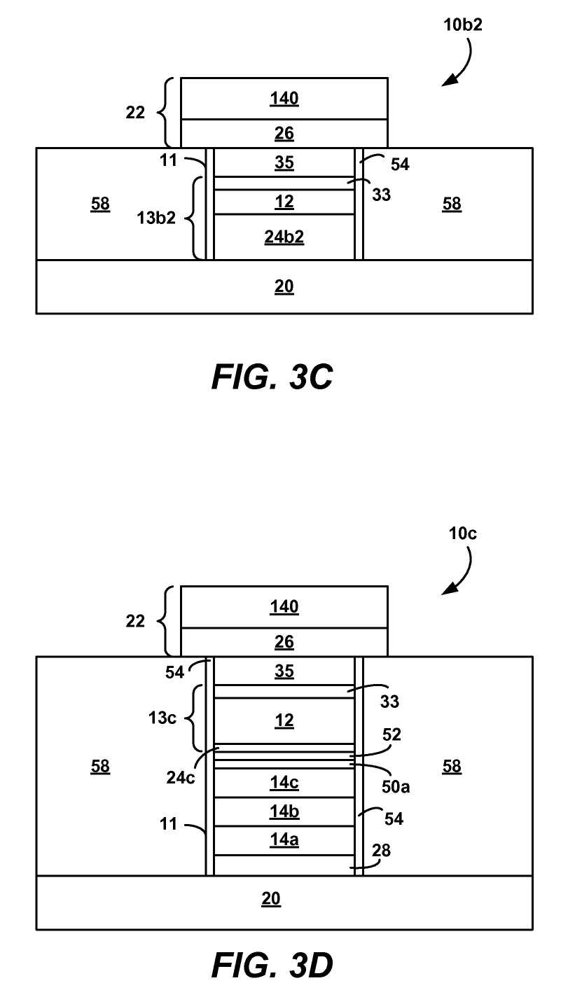

Exemplary embodiments of memory cell 10, carbon-based reversible resistance-switching element 12 and steering element 14 are described below with reference to FIGS. 2A-2D and FIGS. 3A-3C.

### Exemplary Embodiments of Memory Cells and Memory Arrays

FIG. 2A is a simplified perspective view of an exemplary embodiment of a memory cell 10 in accordance with this invention. Memory cell 10 includes a pillar 11 coupled between a first conductor 20 and a second conductor 22. Pillar 11 includes a carbon-based reversible resistance-switching element 12 coupled in series with a steering element 14. In some embodiments, steering element may be omitted from pillar 11, and memory cell 10 may be used with a remotely located steering element. In some embodiments, a barrier layer 24 may be formed between carbon-based reversible resistance-switching element 12 and steering element 14, a barrier layer 28 may be formed between steering element 14 and first conductor 20, and a barrier layer 33 may be formed between carbon-based reversible resistance-switching element 12 and a metal layer 35. Barrier layer 24, carbon-based reversible resistance-switching element 12, and barrier layer 33 form a MIM structure, with barrier layer 24 and barrier layer 33 forming the bottom and top electrodes, respectively, of the MIM structure. As described in more detail below, in exemplary embodiments of this invention, bottom electrode 24 may include a thin, degenerately-doped semiconductor material (e.g., silicon), a conductive silicide (e.g., TiSi), or a reduced volume/area layer of TiN. Barrier layer 28 and top electrode 33 may include TiN, TaN, WN, or other similar barrier layer. In some embodiments, top electrode 33 and metal layer 35 may be formed as part of second conductor 22.

Carbon-based reversible resistance-switching element 12 may include a carbon-based material suitable for use in a memory cell. In exemplary embodiments of this invention, carbon-based reversible resistance-switching element 12 may include graphitic carbon. For example, in some embodiments, graphitic carbon reversible resistivity switching materials may be formed by PECVD, such as described in U.S. patent application Ser. No. 12/499,467, filed Jul. 8, 2009, and titled “Carbon-Based Resistivity-Switching Materials And Methods Of Forming The Same,” (the “'467 application”) (Docket No. SD-MXA-294), which is incorporated by reference herein in its entirety for all purposes. In other embodiments, carbon-based reversible resistance-switching element 12 may include other carbon-based materials such as graphene, graphite, carbon nano-tube materials, DLC, silicon carbide, boron carbide, or other similar carbon-based materials. For simplicity, carbon-based reversible resistance-switching element 12 will be referred to in the remaining discussion interchangeably as “carbon element 12,” or “carbon layer 12.”

In an exemplary embodiment of this invention, steering element 14 includes a diode. In this discussion, steering element 14 is sometimes referred to as “diode 14.” Diode 14 may include any suitable diode such as a vertical polycrystalline p-n or p-i-n diode, whether upward pointing with an n-region above a p-region of the diode or downward pointing with a p-region above an n-region of the diode. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed.

First conductor 20 and/or second conductor 22 may include any suitable conductive material such as tungsten, any appropriate metal, heavily doped semiconductor material, a conductive silicide, a conductive silicide-germanide, a conductive germanide, or the like. In the embodiment of FIG. 2A, first and second conductors 20 and 22, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with the first conductor 20 and/or second conductor 22 to improve device performance and/or aid in device fabrication.

FIG. 2B is a simplified perspective view of a portion of a first memory level 30 formed from a plurality of memory cells 10, such as memory cell 10 of FIG. 2A. For simplicity, carbon element 12, diode 14, bottom electrode 24a, barrier layer 28, top electrode 33, and metal layer 35 are not separately shown. Memory array 30 is a “cross-point” array including a plurality of bit lines (second conductors 22) and word lines (first conductors 20) to which multiple memory cells are coupled (as shown). Other memory array configurations may be used, as may multiple levels of memory.

For example, FIG. 2C is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 2C for simplicity. Other memory array configurations may be used, as may additional levels of memory. In the embodiment of FIG. 2C, all diodes may “point” in the same direction, such as upward or downward depending on whether p-i-n diodes having a p-doped region on the bottom or top of the diodes are employed, simplifying diode fabrication.

For example, in some embodiments, the memory levels may be formed as described in U.S. Pat. No. 6,952,030, titled “High-Density Three-Dimensional Memory Cell,” which is incorporated by reference herein in its entirety for all purposes. For instance, the upper conductors of a first memory level may be used as the lower conductors of a second memory level that is positioned above the first memory level as shown in FIG. 2D. In such embodiments, the diodes on adjacent memory levels preferably point in opposite directions as described in U.S. patent application Ser. No. 11/692,151, filed Mar. 27, 2007, and titled “Large Array Of Upward Pointing P-I-N Diodes Having Large And Uniform Current,” (the “'151 Application”) (Docket No. SD-MXA-196X), which is incorporated by reference herein in its entirety for all purposes. For example, as shown in FIG. 2D, the diodes of the first memory level 42 may be upward pointing diodes as indicated by arrow D1 (e.g., with p regions at the bottom of the diodes), whereas the diodes of the second memory level 44 may be downward pointing diodes as indicated by arrow D2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

FIGS. 3A-3D illustrate cross-sectional views of exemplary embodiments of memory cell 10 of FIG. 2A formed on a substrate, such as a wafer (not shown). In a first exemplary embodiment shown in FIG. 3A, memory cell 10a includes a pillar 11 coupled between first and second conductors 20 and 22, respectively. Pillar 11 includes carbon element 12 coupled in series with diode 14, and also may include bottom electrode 24a, barrier layer 28, top electrode 33, a silicide layer 50, a silicide-forming metal layer 52, and a metal layer 35. Carbon element 12, bottom electrode 24a and top electrode 33 form a MIM structure 13a. A dielectric layer 58 substantially surrounds pillar 11. In some embodiments, a sidewall liner 54 separates selected layers of pillar 11 from dielectric layer 58. Adhesion layers, antireflective coating layers and/or the like (not shown) may be used with first and/or second conductors 20 and 22, respectively, to improve device performance and/or facilitate device fabrication.

First conductor 20 may include any suitable conductive material such as tungsten, any appropriate metal, heavily doped semiconductor material, a conductive silicide, a conductive silicide-germanide, a conductive germanide, or the like. Second conductor 22 includes a barrier layer 26, which may include titanium nitride or other similar barrier layer material, and conductive layer 140, which may include any suitable conductive material such as tungsten, any appropriate metal, heavily doped semiconductor material, a conductive silicide, a conductive silicide-germanide, a conductive germanide, or the like.

Diode 14 may be a vertical p-n or p-i-n diode, which may either point upward or downward. In the embodiment of FIG. 2D in which adjacent memory levels share conductors, adjacent memory levels preferably have diodes that point in opposite directions such as downward-pointing p-i-n diodes for a first memory level and upward-pointing p-i-n diodes for an adjacent, second memory level (or vice versa).

In some embodiments, diode 14 may be formed from a polycrystalline semiconductor material such as polysilicon, a polycrystalline silicon-germanium alloy, polygermanium or any other suitable material. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed.

In some embodiments, a thin germanium and/or silicon-germanium alloy layer (not shown) may be formed on n+ polysilicon region 14a to prevent and/or reduce dopant migration from n+ polysilicon region 14a into intrinsic region 14b. Use of such a layer is described, for example, in U.S. patent application Ser. No. 11/298,331, filed Dec. 9, 2005, and titled “Deposited Semiconductor Structure To Minimize N-Type Dopant Diffusion And Method Of Making,” (the “'331 Application”) (Docket No. SD-MA-121-1), which is incorporated by reference herein in its entirety for all purposes. In some embodiments, a few hundred angstroms or less of silicon-germanium alloy with about 10 atomic percent (“at %”) or more of germanium may be employed.

A barrier layer 28, such as titanium nitride, tantalum nitride, tungsten nitride, or other similar barrier layer material, may be formed between the first conductor 20 and the n+ region 14a (e.g., to prevent and/or reduce migration of metal atoms into the polysilicon regions).

If diode 14 is fabricated from deposited silicon (e.g., amorphous or polycrystalline), a silicide layer 50 may be formed on diode 14 to place the deposited silicon in a low resistivity state, as fabricated. Such a low resistivity state allows for easier programming of memory cell 10, as a large voltage is not required to switch the deposited silicon to a low resistivity state. For example, a silicide-forming metal layer 52 such as titanium or cobalt may be deposited on p+ polysilicon region 14c. In some embodiments, an additional nitride layer (not shown) may be formed at a top surface of silicide-forming metal layer 52. In particular, for highly reactive metals, such as titanium, an additional cap layer such as TiN layer may be formed on silicide-forming metal layer 52. Thus, in such embodiments, a Ti/TiN stack is formed on top of p+ polysilicon region 14c.

A rapid thermal anneal (“RTA”) step may then be performed to form silicide regions by reaction of silicide-forming metal layer 52 with p+ region 14c. The RTA step may be performed at a temperature between about 650° C. and about 750° C., more generally between about 600° C. and about 800° C., preferably at about 750° C., for a duration between about 10 seconds and about 60 seconds, more generally between about 10 seconds and about 90 seconds, preferably about 1 minute, and causes silicide-forming metal layer 52 and the deposited silicon of diode 14 to interact to form silicide layer 50, consuming all or a portion of the silicide-forming metal layer 52.

As described in U.S. Pat. No. 7,176,064, titled “Memory Cell Comprising A Semiconductor Junction Diode Crystallized Adjacent To A Silicide,” which is incorporated by reference herein in its entirety for all purposes, silicide-forming materials such as titanium and/or cobalt react with deposited silicon during annealing to form a silicide layer. The lattice spacing of titanium silicide and cobalt silicide are close to that of silicon, and it appears that such silicide layers may serve as “crystallization templates” or “seeds” for adjacent deposited silicon as the deposited silicon crystallizes (e.g., silicide layer 50 enhances the crystalline structure of silicon diode 14 during annealing). Lower resistivity silicon thereby is provided. Similar results may be achieved for silicon-germanium alloy and/or germanium diodes.

In embodiments in which a nitride layer was formed at a top surface of silicide-forming metal layer 52, following the RTA step, the nitride layer may be stripped using a wet chemistry. For example, if silicide-forming metal layer 52 includes a TiN top layer, a wet chemistry (e.g., H₂O:H₂O₂:NH₄OH in a 10:2:1 ratio at a temperature of between about 40-60° C.) may be used to strip any residual TiN.

As discussed above, in a conventional MIM structure, a carbon layer sandwiched between top and bottom electrodes may be susceptible to delamination and/or peeling from bottom electrode material (often TiN) a result of excessive stress due to the difference in thermal expansion coefficients between the carbon material and TiN, and weak adhesion between carbon material and TiN. In accordance with embodiments of the invention, a carbon-based MIM structure is formed that is less prone to such failure by reducing the difference in thermal expansion coefficients between the carbon material and the adjacent bottom electrode material.

In particular, in one exemplary embodiment, a carbon-based MIM structure is formed in which the bottom electrode is fabricated as a relatively thin, degenerately doped layer of semiconductor material. In a second exemplary embodiment, a carbon-based MIM structure is formed in which the bottom electrode is fabricated as a layer of a conductive silicide. In a third exemplary embodiment, a carbon-based MIM structure is formed in which the bottom electrode has a reduced volume and/or reduced interface area between the bottom electrode and the carbon material. Each of these will be discussed in turn.

### Degenerately Doped Semiconductor Bottom Electrode

In the exemplary embodiment of FIG. 3A, MIM structure 13a includes carbon layer 12 sandwiched between top electrode 33 and bottom electrode 24a. Bottom electrode 24a may be a thin, degenerately doped layer of semiconductor material (e.g., silicon, germanium, a silicon-germanium alloy, or other similar semiconductor material). Bottom electrode 24a may be doped with boron, aluminum, gallium, indium, thallium, phosphorous, arsenic, antimony, or other similar dopant.

For example, bottom electrode 24a may be between about 50-100 angstroms, more generally between about 50-200 angstroms of boron-doped silicon having a doping concentration of between about 10²⁰-10²³ cm⁻³, more generally between about 10¹⁸-10²³ cm⁻³. Other semiconductor materials, layer thicknesses, dopants, and/or doping concentrations may be used. Bottom electrode 24a may be formed by PECVD, thermal chemical vapor deposition, low pressure chemical vapor deposition (“LPCVD”), PVD, ALD, or other similar formation techniques using a silicon-containing precursor gas, such as silane (“SiH₄”), disilane (“Si₂H₆”), or other similar silicon-containing gas.

For example, Table 1 describes exemplary LPCVD process conditions for forming degenerately doped silicon for both p-type and n-type dopants using reacting gases such as SiH₄ and boron chloride (“BCL₃”), and SiH₄ and phosphene (“PH₃”), respectively:

TABLE 1
EXEMPLARY LPCVD PROCESS PARAMETERS

| | p+ silicon | | n+ silicon | |
|---|---|---|---|---|
| PROCESS | EXEMPLARY | PREFERRED | EXEMPLARY | PREFERRED |
| PARAMETER | RANGE | RANGE | RANGE | RANGE |
| SiH₄ Flow Rate | 125-375 | 225-275 | 125-375 | 225-275 |
| (sccm) | | | | |
| BCl₃ Flow Rate | 20-80 | 30-50 | — | — |
| (sccm) | | | | |
| PH₃ Flow Rate | — | — | 20-80 | 25-35 |
| (sccm) | | | | |
| He Flow rate | 100-300 | 150-250 | 100-300 | 150-250 |
| (sccm) | | | | |
| Chamber | 200-1000 | 300-500 | 200-1000 | 300-500 |
| Pressure (mTorr) | | | | |
| Process | 450-650 | 500-600 | 450-650 | 500-600 |
| Temperature (° C.) | | | | |

Other reacting gases, flow rates, pressures and/or temperatures may be used.

By way of another example, Table 2 describes exemplary PECVD process conditions for forming degenerately doped silicon for both p-type and n-type dopants using reacting gases such as SiH₄ and diborane (“B₂H₆”), and SiH₄ and PH₃, respectively:

TABLE 2
EXEMPLARY PECVD PROCESS PARAMETERS

| | p+ silicon | | n+ silicon | |
|---|---|---|---|---|
| PROCESS | EXEMPLARY | PREFERRED | EXEMPLARY | PREFERRED |
| PARAMETER | RANGE | RANGE | RANGE | RANGE |
| SiH₄ Flow Rate | 10-200 | 15-100 | 10-200 | 15-100 |
| (sccm) | | | | |
| BCl₃ Flow Rate | 10-200 | 15-100 | — | — |
| (sccm) | | | | |
| PH₃ Flow Rate | — | — | 10-200 | 15-200 |
| (sccm) | | | | |
| He Flow rate | 1000-10000 | 1000-5000 | 1000-10000 | 1000-5000 |
| (sccm) | | | | |
| Chamber | 3-8 | 4-6 | 3-8 | 4-6 |
| Pressure (Torr) | | | | |
| Process | 450-600 | 480-550 | 450-600 | 480-550 |
| Temperature (° C.) | | | | |

Other reacting gases, flow rates, pressures and/or temperatures may be used.

Although not wanting to be bound by any particular theory, it is believed that by forming bottom electrode 24a using a relatively thin layer of degenerately doped semiconductor material, thermal-induced stress in carbon layer 12 will be reduced compared to a MIM structure that uses a conventional TiN bottom electrode. For example, in an experiment in which a 400 angstrom carbon material layer was formed on a 1200 angstrom Si sheet film by a PECVD process at 550° C., a thermal induced compressive stress in the carbon element was measured at about 300 MPa, which is much lower than the tensile stress between carbon and a comparable TiN film. In addition, the interface adhesion strength between carbon and silicon is much greater than the interface adhesion strength between carbon and TiN. Further, by using a relatively thin layer of degenerately doped semiconductor material, it is believed that bottom electrode 24a will have relatively low resistivity, and will not switch (lightly doped polycrystalline silicon has been known to switch).

Referring again to FIG. 3A, carbon layer 12 may be formed by any suitable process, and at any suitable thickness. For example, in one embodiment, carbon layer 12 is graphitic carbon formed by PECVD, such as described in the '467 application, and having a thickness of between about 100 and about 600 angstroms, more generally between about 1 and about 1000 angstroms. Alternatively, carbon layer 12 may be formed by chemical vapor deposition (“CVD”), high density plasma (“HDP”) deposition, PVD, or other similar methods. As mentioned above, carbon layer 12 alternatively may include one or more of graphene, graphite, carbon nano-tube materials, DLC, silicon carbide, boron carbide, or other similar carbon-based materials. Other carbon materials, formation processes and thicknesses may be used.

Top electrode 33 may be formed above carbon layer 12 by atomic layer deposition (“ALD”), CVD, or other similar processing technique. Top electrode 33 may be between about 50-200 angstroms, more generally between about 20-300 angstroms, of titanium nitride, tungsten nitride, tantalum nitride, or other similar barrier layer material. Other materials and/or thicknesses may be used.

In some embodiments of this invention, a metal layer 35 may be deposited over barrier layer 33. For example, between about 800 and about 1200 angstroms, more generally between about 500 angstroms and about 1500 angstroms, of tungsten may be deposited on barrier layer 33. Other materials and thicknesses may be used. Any suitable method may be used to form metal layer 35. For example, CVD, PVD, or the like may be employed.

In some methods of this invention, a conformal dielectric liner 54 may be formed around the sidewalls of pillar 11. For example, dielectric sidewall liner 54 may include boron nitride, silicon nitride, or another similar dielectric liner material. Dielectric sidewall liner 54 may be formed by ALD, PECVD, or other similar method. Dielectric sidewall liner 54 may protect sidewalls of carbon layer 12 during a subsequent deposition of an oxygen-rich dielectric 58.

### Conductive Silicide Bottom Electrode

In accordance with alternative embodiments of this invention, MIM structures may be formed using conductive silicide bottom electrodes. Such silicide materials may be formed by PVD, PECVD, or other similar method. Examples of such techniques will now be described.

PVD Silicide Formation

Referring now to FIG. 3B, an alternative exemplary memory cell 10b1 is described. Memory cell 10b1 includes MIM structure 13b1, which includes carbon layer 12 sandwiched between top electrode 33 and bottom electrode 24b1. Bottom electrode 24b1 may be a silicide material, such as TiSi, TaSi, WSi, CuSi, or other similar silicide material. For example, bottom electrode 24b1 may be between about 20-30 angstroms, more generally between about 10-50 angstroms of TiSi. Other layer thicknesses may be used.

In an exemplary embodiment of this invention, bottom electrode 24b1 may be formed as described above regarding the formation of silicide layer 50. For example, bottom electrode 24b1 may be formed as a Ti/TiN stack on p+ polysilicon region 14c by PVD. To prevent oxidation of the deposited Ti layer, the TiN layer may be formed on the Ti layer in the same PVD chamber. An RTA step may then be performed to react the Ti layer with p+ region 14c to form TiSi bottom electrode 24b1. The RTA step may be performed at a temperature between about 650° C. and about 750° C., more generally between about 600° C. and about 800° C., preferably at about 750° C., for a duration between about 10 seconds and about 60 seconds, more generally between about 10 seconds and about 90 seconds, preferably about 1 minute. Following the RTA step, the TiN layer may be stripped using a wet chemistry. For example, a wet chemistry (e.g., H₂O:H₂O₂:NH₄OH in a 10:2:1 ratio at a temperature of between about 40-60° C.) may be used to strip any residual TiN.

In-Situ Silicide Formation

Referring now to FIG. 3C, another alternative exemplary memory cell 10b2 is described. Memory cell 10b2 includes MIM structure 13b2, which includes carbon layer 12 sandwiched between top electrode 33 and bottom electrode 24b2. Bottom electrode 24b2 may be a silicide material, such as TiS, TaSi, WSi, CuSi, or other similar silicide material. For example, bottom electrode 24b2 may be between about 20-30 angstroms, more generally between about 10-50 angstroms of TiSi. Other layer thicknesses may be used. In this exemplary embodiment, memory cell 10b2 does not include a steering element. As described above, such memory cells may be used with a remotely located steering element, such as a thin film transistor, diode, or other similar steering element. Persons of ordinary skill in the art will understand that memory cell 10b2 alternatively may include a steering element, such as diode 14.

Bottom electrode 24b2 and carbon layer 12 may be formed by in the same processing chamber (referred to herein as “in-situ formation”). For example, bottom electrode 24b2 may be formed in a PECVD chamber used to form carbon layer 12. First, a metal layer 24b2 (e.g., Ti, Ta, W, Cu or other similar metal) may be formed on first conductor 20 by PVD. For example, bottom electrode 24b2 may be between about 20-30 angstroms, more generally between about 10-50 angstroms of Ti. Other layer materials and thicknesses may be used. Next, the substrate may be placed in a PECVD processing chamber that will be used to form carbon layer 12. A reducing gas, such as NH₃, H₂, or other similar gas may be ignited in a plasma to remove any metal oxide from the surface of metal layer 24b2. Table 3 illustrates exemplary NH₃ and H₂ treatment process parameters:

TABLE 3
EXEMPLARY PECVD OXIDE STRIP PROCESS PARAMETERS

| | NH₃ | | H₂ | |
|---|---|---|---|---|
| PROCESS | EXEMPLARY | PREFERRED | EXEMPLARY | PREFERRED |
| PARAMETER | RANGE | RANGE | RANGE | RANGE |
| NH₃ Flow Rate | 100-5000 | 150-250 | — | — |
| (sccm) | | | | |
| H₂ Flow rate | — | — | 100-5000 | 550-650 |
| (sccm) | | | | |
| N₂ Carrier Flow | 1000-20000 | 9500-10500 | 0-5000 | 0-100 |
| Rate (sccm) | | | | |
| Chamber | 3-8 | 3.5-4.5 | 3-8 | 5-6 |
| Pressure (Torr) | | | | |
| RF Power | 0.3-1.4 | 0.4-0.5 | 0.3-1.4 | 0.9-1.0 |
| Density (W/cm²) | | | | |
| Process | 250-550 | 500-550 | 250-550 | 500-550 |
| Temperature (° C.) | | | | |
| Spacing (mils) | 300-600 | 300-400 | 300-600 | 400-500 |

Next, a silicide layer may be formed on metal layer 24b2 by thermally reacting the metal layer with a silicon-containing precursor gas, such as SiH₄, Si₂H₆, or other similar silicon-containing gas. For example, Table 4 describes exemplary process conditions for in-situ formation of a TiSi bottom electrode 24b2 using silane (commonly referred to as a “silane soak”):

TABLE 4
EXEMPLARY SILANE SOAK PROCESS PARAMETERS

| | EXEMPLARY | PREFERRED |
|---|---|---|
| PROCESS PARAMETER | RANGE | RANGE |
| SiH₄ Flow Rate (sccm) | 200-500 | 450-500 |
| N₂ Carrier Flow rate (sccm) | 1000-10000 | 4500-5500 |
| Chamber Pressure (Torr) | 3-8 | 4.5-5.5 |
| Process Temperature (° C.) | 350-550 | 500-550 |
| Process Time (seconds) | 10-120 | 20-30 |
| Spacing (mils) | 200-800 | 400-500 |

In accordance with embodiments of this invention, a relatively high N₂ flow rate may be used to uniformly distribute silane across the substrate. Further, soaking silane into the Ti layer may be significantly promoted by increasing the soaking temperature, time and/or silane concentration. Moreover, persons of ordinary skill in the art will understand that multiple cycles of the silane soak may be performed to form MSiₓ, where M is the metal layer (e.g., Ti), and x=1-6. Finally, persons of ordinary skill in the art will understand that silicide bottom electrode 24b2 may be formed in situ in other types of processing chambers, such as processing chambers for ALD, thermal CVD, LPCVD, and other similar processing chambers, used to form carbon layer 12.

### Reduced Volume/Contact Area Bottom Electrode

Referring now to FIG. 3D, still another alternative exemplary memory cell 10c is described. Memory cell 10c includes MIM structure 13c, which includes carbon layer 12 sandwiched between top electrode 33 and bottom electrode 24c. Bottom electrode 24c may be formed using a conventional bottom electrode material, but may be formed to have a reduced volume and/or a reduced interface area between the bottom electrode and carbon layer 12. For example, bottom electrode 24c may be between about 25-50 angstroms, more generally between about 25-100 angstroms, of TiN, TaN, WN, Mo, or other similar barrier layer material. Other thickness and materials may be used.

Thus, whereas a conventionally formed bottom electrode layer may be between about 50-100 angstroms of titanium nitride, bottom electrode 24c has a thickness of about half that amount. In this regard, the thickness and volume of bottom electrode 24c is reduced compared to a conventionally-formed bottom electrode. Research has shown that blanket film interface stress scales with film thickness. Thus, although not wanting to be bound by any particular theory, it is believed that reducing the thickness and volume of bottom electrode 24c may reduce thermal expansion-coefficient mismatch-induced interface stress in carbon layer 12.

In addition, or alternatively, the diameter of bottom electrode 24c may be made smaller than the diameter of carbon layer 12 to reduce the interface area between carbon layer 12 and bottom electrode 24c. For example, the diameter of bottom electrode 24c may be reduced by etching, shrinking, or other similar method. Although not wanting to be bound by any particular theory, it is believed that reducing the interface area between carbon layer 12 and bottom electrode 24c may reduce thermal expansion-coefficient mismatch-induced interface stress in carbon layer 12.

Although the exemplary embodiments illustrated in FIGS. 3A, 3B and 3D show carbon layer 12 above diode 14, persons of ordinary skill in the art will understand that carbon layer 12 alternatively may be positioned below diode 14. Further, although the exemplary memory cells 10a, 10b1 and 10c include MIM structures 13a, 13b1 and 13c, respectively, coupled to diodes 14, persons of ordinary skill in the art will understand that memory cells 10 in accordance with this invention alternatively may include MIM structures coupled between first and second conductors 20 and 22, respectively, for use with remotely fabricated steering elements.

### Exemplary Fabrication Processes for Memory Cells

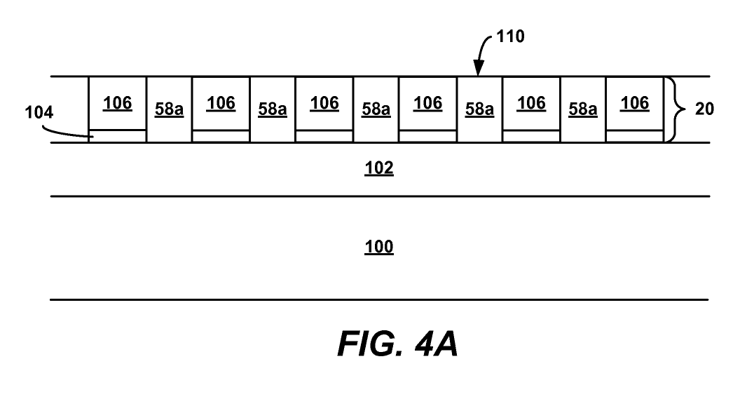

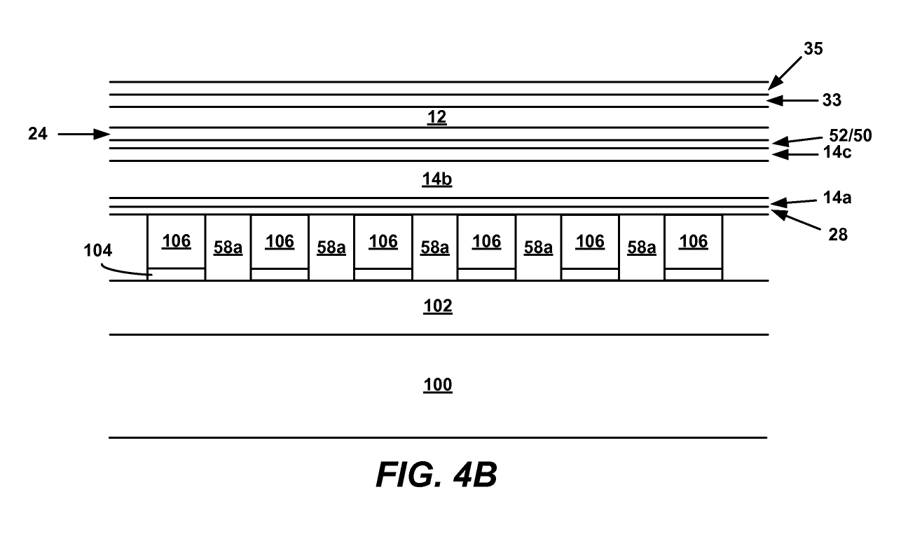

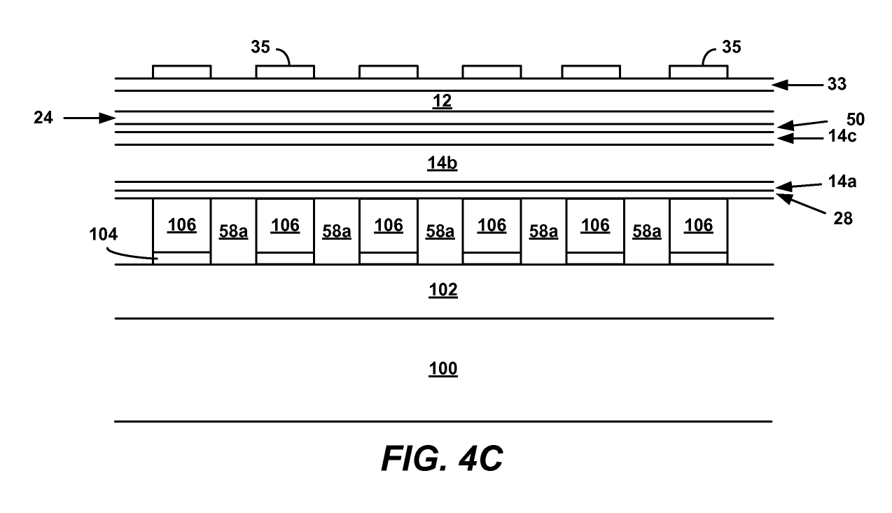

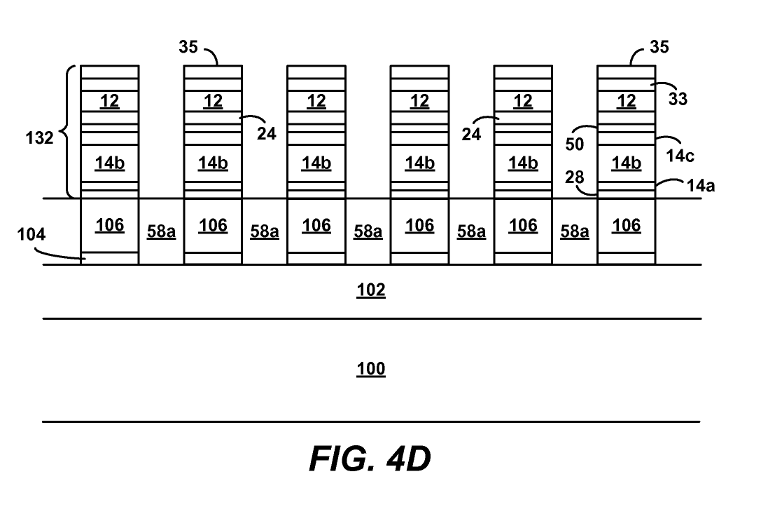

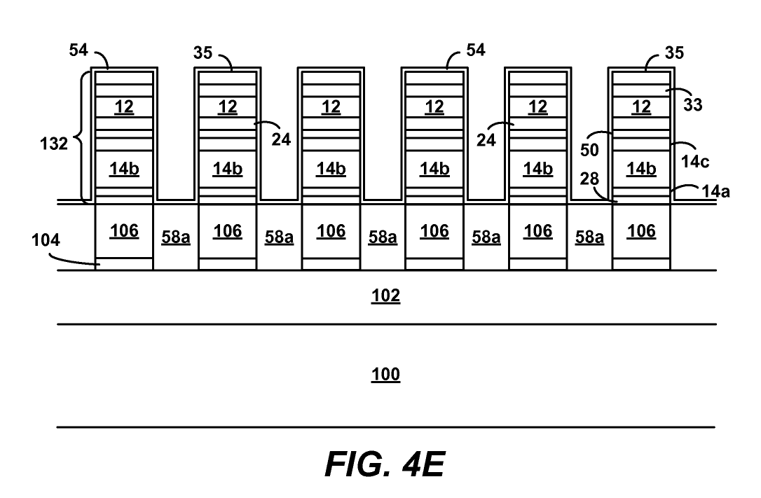

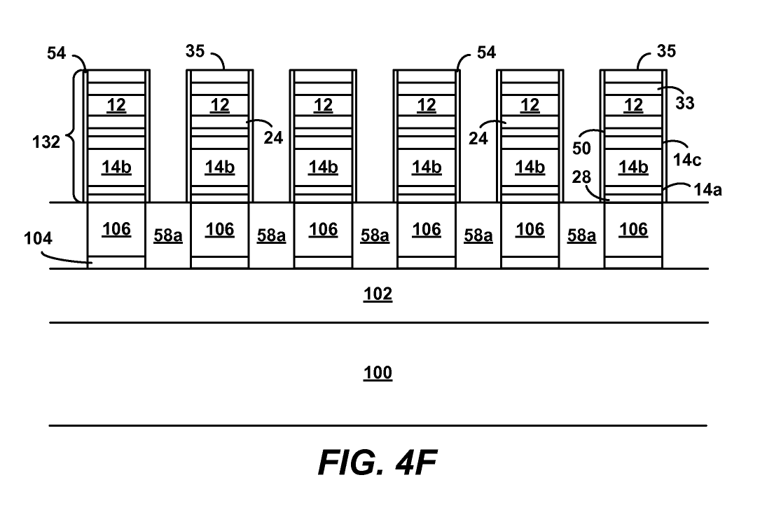

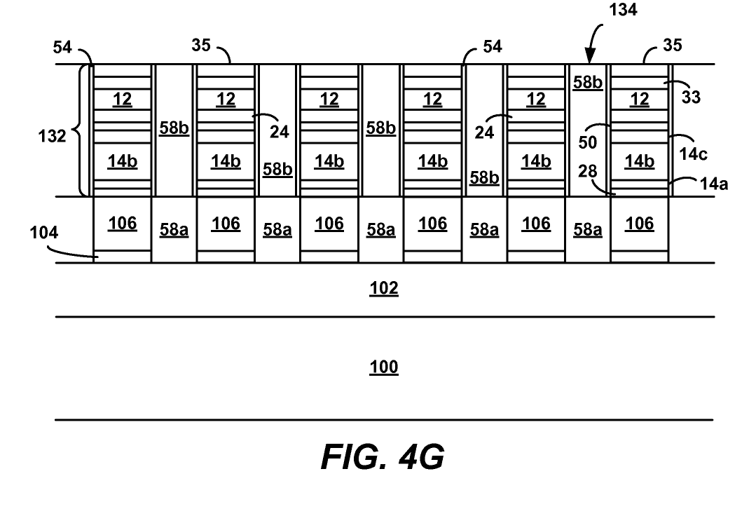

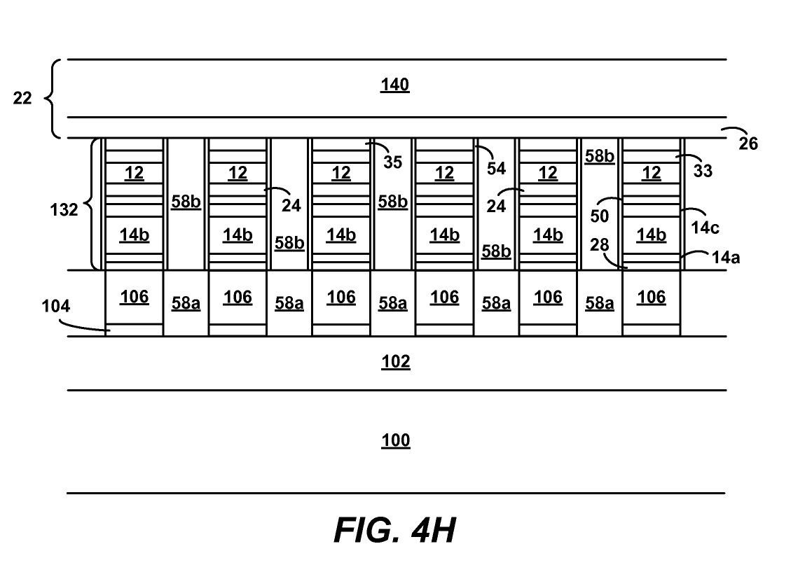

Referring now to FIGS. 4A-4G, an exemplary method of forming an exemplary memory level in accordance with this invention is described. In particular, FIGS. 4A-4G illustrate an exemplary method of forming an exemplary memory level including memory cells 10, such as illustrated in FIGS. 3A-3D. As will be described below, the first memory level includes a plurality of memory cells that each include a steering element and a carbon-based reversible resistance switching element coupled to the steering element. Additional memory levels may be fabricated above the first memory level (as described previously with reference to FIGS. 2C-2D).

With reference to FIG. 4A, substrate 100 is shown as having already undergone several processing steps. Substrate 100 may be any suitable substrate such as a silicon, germanium, silicon-germanium, undoped, doped, bulk, silicon-on-insulator (“SOI”) or other substrate with or without additional circuitry. For example, substrate 100 may include one or more n-well or p-well regions (not shown).

Isolation layer 102 is formed above substrate 100. In some embodiments, isolation layer 102 may be a layer of silicon dioxide, silicon nitride, silicon oxynitride or any other suitable insulating layer.

Following formation of isolation layer 102, an adhesion layer 104 is formed over isolation layer 102 (e.g., by physical vapor deposition or another method). For example, adhesion layer 104 may be about 20 and about 500 angstroms, and preferably about 100 angstroms, of titanium nitride or another suitable adhesion layer such as tantalum nitride, tungsten nitride, combinations of one or more adhesion layers, or the like. Other adhesion layer materials and/or thicknesses may be employed. In some embodiments, adhesion layer 104 may be optional.

After formation of adhesion layer 104, a conductive layer 106 is deposited over adhesion layer 104. Conductive layer 106 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 106 may comprise about 200 and about 2500 angstroms of tungsten. Other conductive layer materials and/or thicknesses may be used.

Following formation of conductive layer 106, adhesion layer 104 and conductive layer 106 are patterned and etched. For example, adhesion layer 104 and conductive layer 106 may be patterned and etched using conventional lithography techniques, with a soft or hard mask, and wet or dry etch processing. In at least one embodiment, adhesion layer 104 and conductive layer 106 are patterned and etched to form substantially parallel, substantially co-planar first conductors 20. Exemplary widths for first conductors 20 and/or spacings between first conductors 20 range from about 200 and about 2500 angstroms, although other conductor widths and/or spacings may be used.

After first conductors 20 have been formed, a dielectric layer 58a is formed over substrate 100 to fill the voids between first conductors 20. For example, approximately 3000-7000 angstroms of silicon dioxide may be deposited on the substrate 100 and planarized using chemical mechanical polishing or an etchback process to form a planar surface 110. Planar surface 110 includes exposed top surfaces of first conductors 20 separated by dielectric material (as shown). Other dielectric materials such as silicon nitride, silicon oxynitride, low K dielectrics, etc., and/or other dielectric layer thicknesses may be used. Exemplary low K dielectrics include carbon doped oxides, silicon carbon layers, or the like.

In other embodiments of the invention, first conductors 20 may be formed using a damascene process in which dielectric layer 58a is formed, patterned and etched to create openings or voids for first conductors 20. The openings or voids then may be filled with adhesion layer 104 and conductive layer 106 (and/or a conductive seed, conductive fill and/or barrier layer if needed). Adhesion layer 104 and conductive layer 106 then may be planarized to form planar surface 110. In such an embodiment, adhesion layer 104 will line the bottom and sidewalls of each opening or void.

Following planarization, the diode structures of each memory cell are formed. With reference to FIG. 4B, a barrier layer 28 is formed over planarized top surface 110 of substrate 100. Barrier layer 28 may be about 20 and about 500 angstroms, and preferably about 100 angstroms, of titanium nitride or another suitable barrier layer such as tantalum nitride, tungsten nitride, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 28, deposition of the semiconductor material used to form the diode of each memory cell begins (e.g., diode 14 in FIGS. 1 and 3). Each diode may be a vertical p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, downward-pointing diode is described herein. It will be understood that other materials and/or diode configurations may be used.

With reference to FIG. 4B, following formation of barrier layer 28, a heavily doped n+ silicon layer 14a is deposited on barrier layer 28. In some embodiments, n+ silicon layer 14a is in an amorphous state as deposited. In other embodiments, n+ silicon layer 14a is in a polycrystalline state as deposited. CVD or another suitable process may be employed to deposit n+ silicon layer 14a. In at least one embodiment, n+ silicon layer 14a may be formed, for example, from about 100 and about 1000 angstroms, preferably about 100 angstroms, of phosphorus or arsenic doped silicon having a doping concentration of about 10²¹ cm⁻³. Other layer thicknesses, doping types and/or doping concentrations may be used. N+ silicon layer 14a may be doped in situ, for example, by flowing a donor gas during deposition. Other doping methods may be used (e.g., implantation).

After deposition of n+ silicon layer 14a, a lightly doped, intrinsic and/or unintentionally doped silicon layer 14b may be formed over n+ silicon layer 14a. In some embodiments, intrinsic silicon layer 14b may be in an amorphous state as deposited. In other embodiments, intrinsic silicon layer 14b may be in a polycrystalline state as deposited. CVD or another suitable deposition method may be employed to deposit intrinsic silicon layer 14b. In at least one embodiment, intrinsic silicon layer 14b may be about 500 and about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on n+ silicon layer 14a prior to depositing intrinsic silicon layer 14b to prevent and/or reduce dopant migration from n+silicon layer 14a into intrinsic silicon layer 14b (as described in the '331 Application, previously incorporated).

Heavily doped, p-type silicon may be either deposited and doped by ion implantation or may be doped in situ during deposition to form a p+ silicon layer 14c. For example, a blanket p+ implant may be employed to implant boron a predetermined depth within intrinsic silicon layer 14b. Exemplary implantable molecular ions include BF₂, BF₃, B and the like. In some embodiments, an implant dose of about 1-5×10¹⁵ ions/cm² may be employed. Other implant species and/or doses may be used. Further, in some embodiments, a diffusion process may be employed. In at least one embodiment, the resultant p+ silicon layer 14c has a thickness of about 100-700 angstroms, although other p+ silicon layer sizes may be used.

Following formation of p+ silicon layer 14c, a silicide-forming metal layer 52 is deposited over p+ silicon layer 14c. Exemplary silicide-forming metals include sputter or otherwise deposited Ti or cobalt. In some embodiments, silicide-forming metal layer 52 has a thickness of about 10 and about 200 angstroms, preferably about 20 and about 50 angstroms and more preferably about 20 angstroms. Other silicide-forming metal layer materials and/or thicknesses may be used. A nitride layer (not shown) may be formed at the top of silicide-forming metal layer 52.

Following formation of silicide-forming metal layer 52, an RTA step may be performed to form silicide layer 50, consuming all or a portion of the silicide-forming metal layer 52. The RTA step may be performed at a temperature between about 650° C. and about 750° C., more generally between about 600° C. and about 800° C., preferably at about 750° C., for a duration between about 10 seconds and about 60 seconds, more generally between about 10 seconds and about 90 seconds, preferably about 60 seconds. Following the RTA step, any residual nitride layer from silicide-forming metal layer 52 may be stripped using a wet chemistry, as described above, and as is known in the art.

Following the RTA step and the nitride strip step, a bottom electrode 24 is deposited. As described above in connection with FIG. 3A, bottom electrode 24 may be a thin, degenerately doped layer of semiconductor material (e.g., silicon, germanium, a silicon-germanium alloy, or other similar semiconductor material). For example, bottom electrode 24 may be between about 50-100 angstroms, more generally between about 50-200 angstroms of boron-doped silicon having a doping concentration of between about 10²⁰-10²³ cm⁻³, more generally between about 10¹⁸-10²³ cm⁻³. For example, bottom electrode 24 may be degenerately doped silicon formed by LPCVD using the process parameters described above in Table 1 or by PECVD using the process parameters described above in Table 2.

Alternatively, bottom electrode 24 may be a silicide layer formed as described above in connection with FIGS. 3B and 3C. For example, bottom electrode 24 may be between about 20-30 angstroms, more generally between about 10-50 angstroms of TiSi formed by in-situ formation, using a process such as described above in Tables 3 and 4.

Alternatively, as described above in connection with FIG. 3D, bottom electrode 24 may be formed using a conventional bottom electrode material, but may be formed to have a reduced volume and/or a reduced interface area between the bottom electrode and carbon layer 12. For example, bottom electrode 24 may be between about 25-50 angstroms, more generally between about 25-100 angstroms, of TiN, TaN, WN, Mo, or other similar barrier layer material.

Next, carbon layer 12 is deposited over barrier layer 24. Carbon layer 12 may be formed by a PECVD method, for example. Other methods may be used, including, without limitation, sputter deposition from a target, PVD, CVD, arc discharge techniques, and laser ablation. Other methods may be used to form carbon layer 12, such as a damascene integration method, for example. Carbon layer 12 may include graphitic carbon. In alternative embodiments, other carbon-based materials may be used, such as graphene, graphite, carbon nano-tube materials, DLC, silicon carbide, boron carbide, or other similar carbon-based materials. Carbon layer 12 is formed having a thickness between about 100 and about 600 angstroms, more generally between about 1 and about 1000 angstroms. Other thicknesses may be used.

Next, barrier layer 33 is formed above carbon layer 12. Barrier layer 33 may be TiN, TaN, WN, Mo, or another suitable barrier layer, combinations of one or more barrier layers, barrier layers in combination with other layers such as Ti/TiN, Ta/TaN, W/WN stacks, or the like. Other barrier layer materials may be employed. Barrier layer 33 may be formed by ALD, such as described in U.S. patent application Ser. No. 12/536,457, filed Aug. 5, 2009, and titled “Memory Cell That Includes A Carbon-Based Memory Element And Methods Of Forming The Same,” (the “'457 Application”) (Docket No. SD-MXA-335), which is incorporated by reference herein in its entirety for all purposes. In other embodiments, barrier layer 33 may be formed using a CVD technique, or other similar deposition technique.

Next, a metal layer 35 may be deposited over barrier layer 33. For example, between about 800 and about 1200 angstroms, more generally between about 500 angstroms and about 1500 angstroms, of tungsten may be deposited on barrier layer 33. Other materials and thicknesses may be used. Any suitable method may be used to form metal layer 35. For example, CVD, PVD, or the like may be employed. As described in more detail below, metal layer 35 may be used as a hard mask layer, and also may be used as a stop during a subsequent chemical mechanical planarization (“CMP”) step. A hard mask is an etched layer which serves to pattern the etch of an underlying layer.

As shown in FIG. 4C, metal layer 35 is patterned and etched to form patterned metal hardmask regions 35. Patterned metal hardmask regions 35 may have about the same pitch and about the same width as conductors 20 below, such that each patterned metal hardmask regions 35 is formed on top of a conductor 20. Some misalignment may be tolerated. Persons of ordinary skill in the art will understand that patterned metal hardmask regions 35 may have a smaller width than conductors 20.

For example, photoresist (“PR”) may be deposited on metal layer 35, patterned using standard photolithography techniques, and then the photoresist may be removed. Alternatively, a hard mask of some other material, for example silicon dioxide, may be formed on top of metal layer 33, with bottom antireflective coating (“BARC”) on top, then patterned and etched. Similarly, dielectric antireflective coating (“DARC”) may be used as a hard mask.

As shown in FIG. 4D, metal hardmask regions 35 are used to pattern and etch barrier layer 33, carbon layer 12, bottom electrode 24, silicide-forming metal layer 52, diode layers 14a-14c and barrier layer 28 to form pillars 132. Pillars 132 may have about the same pitch and about the same width as conductors 20 below, such that each pillar 132 is formed on top of a conductor 20. Some misalignment may be tolerated. Persons of ordinary skill in the art will understand that pillars 132 may have a smaller width than conductors 20.

Any suitable etch chemistries, and any suitable etch parameters, flow rates, chamber pressures, power levels, process temperatures, and/or etch rates may be used. In some embodiments, barrier layer 33, carbon element 12, bottom electrode 24, silicide-forming metal layer 52, diode layers 14a-14c and barrier layer 28 may be patterned using a single etch step. In other embodiments, separate etch steps may be used. The etch proceeds down to dielectric layer 58a.

In some exemplary embodiments, the memory cell layers may be etched using chemistries selected to minimize or avoid damage to carbon material. For example, O₂, CO, N₂, or H₂, or other similar chemistries may be used. In embodiments in which CNT material is used in the memory cells, oxygen (“O₂”), boron trichloride (“BCl₃”) and/or chlorine (“Cl₂”) chemistries, or other similar chemistries, may be used. Any suitable etch parameters, flow rates, chamber pressures, power levels, process temperatures, and/or etch rates may be used. Exemplary methods for etching carbon material are described, for example, in U.S. patent application Ser. No. 12/415,964, “Electronic Devices Including Carbon-Based Films Having Sidewall Liners, and Methods of Forming Such Devices,” filed Mar. 31, 2009 (Docket No. SD-MXA-315), which is incorporated by reference in its entirety for all purposes.

After the memory cell layers have been etched, pillars 132 may be cleaned. In some embodiments, a dilute hydrofluoric/sulfuric acid clean is performed. Post-etch cleaning may be performed in any suitable cleaning tool, such as a Raider tool, available from Semitool of Kalispell, Mont. Exemplary post-etch cleaning may include using ultra-dilute sulfuric acid (e.g., about 1.5-1.8 wt %) for about 60 seconds and ultra-dilute hydrofluoric (“HF”) acid (e.g., about 0.4-0.6 wt %) for about 60 seconds. Megasonics may or may not be used. Alternatively, H₂SO₄ may be used.

In accordance with this invention, and as illustrated in FIG. 4D, a conformal dielectric liner 54 is deposited above and around pillars 132. Dielectric liner 54 may be formed with an oxygen-poor deposition chemistry (e.g., without a high oxygen plasma component) to protect sidewalls of carbon layer 12 during a subsequent deposition of an oxygen-rich gap-fill dielectric 58b (e.g., SiO₂) (not shown in FIG. 4D).

In an exemplary embodiment of this invention, dielectric liner 54 may be formed from BN. Alternatively, dielectric sidewall liner 54 may be formed from other materials, such as SiN, SiₓC_{y}N_{z} and SiₓO_{y}N_{z} (with low O content), where x, y and z are non-zero numbers resulting in stable compounds. Dielectric liner 54 may be formed by ALD, PECVD, or other similar process, such as described in the '457 Application. In some embodiments of this invention, dielectric liner 54 is formed by ALD and has a thickness of between about 100 angstroms and about 250 angstroms, more generally between about 100 angstroms and about 300 angstroms. Other thicknesses may be used.

With reference to FIG. 4E, an anisotropic etch is used to remove lateral portions of dielectric liner 54, leaving only sidewall portions of dielectric liner 54 on the sides of pillars 132. For example, a sputter etch or other suitable process may be used to anisotropically etch liner 54. Sidewall dielectric liner 54 may protect the carbon material of carbon element 12 from damage during deposition of dielectric layer 58b (not shown in FIG. 4E), described below.

Next, a dielectric layer 58b is deposited over pillars 132 to gapfill between pillars 132. For example, approximately 2000-7000 angstroms of silicon dioxide may be deposited and planarized using CMP or an etchback process to remove excess dielectric layer material 58b to form a planar surface 136, resulting in the structure illustrated in FIG. 4F. During the planarization process, barrier layer 33 may be used as a CMP stop. Planar surface 136 includes exposed top surfaces of pillars 132 separated by dielectric material 58b (as shown). Other dielectric materials may be used for the dielectric layer 58b such as silicon nitride, silicon oxynitride, low K dielectrics, etc., and/or other dielectric layer thicknesses may be used. Exemplary low K dielectrics include carbon doped oxides, silicon carbon layers, or the like.

With reference to FIG. 4G, second conductors 22 may be formed above pillars 132 in a manner similar to the formation of first conductors 20. For example, in some embodiments, one or more barrier layers and/or adhesion layers 26 may be deposited over pillars 132 prior to deposition of a conductive layer 140 used to form second conductors 22.

Conductive layer 140 may be formed from any suitable conductive material such as tungsten, another suitable metal, heavily doped semiconductor material, a conductive silicide, a conductive silicide-germanide, a conductive germanide, or the like deposited by PVD or any other any suitable method (e.g., CVD, etc.). Other conductive layer materials may be used. Barrier layers and/or adhesion layers 26 may include titanium nitride or another suitable layer such as tantalum nitride, tungsten nitride, combinations of one or more layers, or any other suitable material(s). The deposited conductive layer 140 and bather and/or adhesion layer 26 may be patterned and etched to form second conductors 22. In at least one embodiment, second conductors 22 are substantially parallel, substantially coplanar conductors that extend in a different direction than first conductors 20.

In other embodiments of the invention, second conductors 22 may be formed using a damascene process in which a dielectric layer is formed, patterned and etched to create openings or voids for conductors 22. The openings or voids may be filled with adhesion layer 26 and conductive layer 140 (and/or a conductive seed, conductive fill and/or barrier layer if needed). Adhesion layer 26 and conductive layer 140 then may be planarized to form a planar surface.

Following formation of second conductors 22, the resultant structure may be annealed to crystallize the deposited semiconductor material of diodes 14 (and/or to form silicide regions by reaction of the silicide-forming metal layer 52 with p+ region 14c). The lattice spacing of titanium silicide and cobalt silicide are close to that of silicon, and it appears that silicide layers 50 may serve as “crystallization templates” or “seeds” for adjacent deposited silicon as the deposited silicon crystallizes (e.g., silicide layer 50 enhances the crystalline structure of silicon diode 14 during annealing at temps of about 600-800° C.). Lower resistivity diode material thereby is provided. Similar results may be achieved for silicon-germanium alloy and/or germanium diodes.

Thus in at least one embodiment, a crystallization anneal may be performed for about 10 seconds and about 2 minutes in nitrogen at a temperature of about 600 to 800° C., and more preferably between about 650 to 750° C. Other annealing times, temperatures and/or environments may be used.

Persons of ordinary skill in the art will understand that alternative memory cells in accordance with this invention may be fabricated in other similar techniques. For example, memory cells may be formed that include reversible resistance switching element 12 below diode 14. In addition, memory cells in accordance with this invention may be used with a remotely located steering elements, such as a thin film transistors, diodes, or other similar steering elements. In addition, although FIGS. 4A-4G illustrate exemplary “straight integration” methods of forming memory levels in accordance with this invention, persons of ordinary skill in the art will understand that damascene integration methods alternatively may be used.

The foregoing description discloses only exemplary embodiments of the invention. Modifications of the above disclosed apparatus and methods which fall within the scope of the invention will be readily apparent to those of ordinary skill in the art. Although the invention has been described primarily with reference to graphitic carbon, other carbon-based materials may be similarly used.

Accordingly, although the present invention has been disclosed in connection with exemplary embodiments thereof, it should be understood that other embodiments may fall within the spirit and scope of the invention, as defined by the following claims.

1. A method of forming a reversible resistance-switching metal-insulator-metal (“MIM”) stack, the method comprising:
forming a first conducting layer comprising a degenerately doped semiconductor material; and
forming a carbon-based reversible resistance-switching material above the first conducting layer.

2. The method of claim 1, wherein the first conducting layer comprises one or more of silicon, germanium, and a silicon-germanium alloy.

3. The method of claim 1, wherein the first conducting layer comprises one or more of boron, aluminum, gallium, indium, thallium, phosphorous, arsenic, and antimony.

4. The method of claim 1, wherein the first conducting layer has a doping concentration between about 10¹⁸/cm³ and about 10²³/cm³.

5. The method of claim 1, wherein the first conducting layer has a doping concentration between about 10²⁰/cm³ and about 10²³/cm³.

6. The method of claim 1, wherein the first conducting layer is formed by any of plasma-enhanced chemical vapor deposition (“PECVD”), thermal chemical vapor deposition, low pressure chemical vapor deposition (“LPCVD”), physical vapor deposition and atomic layer deposition.

7. The method of claim 1, wherein forming the first conducting layer comprises using a PECVD process using one or more of silane, disilane, boron chloride, diborane, phosphene and helium gasses.

8. The method of claim 7, wherein the PECVD process uses silane at a flow rate between about 10 standard cubic centimeters per minute and about 200 standard cubic centimeters per minute.

9. The method of claim 7, wherein the PECVD process uses diborane at a flow rate between about 10 standard cubic centimeters per minute and about 200 standard cubic centimeters per minute.

10. The method of claim 7, wherein the PECVD process uses phosphene at a flow rate between about 10 standard cubic centimeters per minute and about 200 standard cubic centimeters per minute.

11. The method of claim 7, wherein the PECVD process is performed at a temperature of between about 450° C. and about 600° C.

12. The method of claim 7, wherein the PECVD process is performed at a pressure of between about 3 Torr and about 8 Torr.

13. The method of claim 1, wherein forming the first conducting layer comprises using an LPCVD process using one or more of silane, disilane, boron chloride, diborane, phosphene and helium gasses.

14. The method of claim 13, wherein the LPCVD process uses silane at a flow rate between about 125 standard cubic centimeters per minute and about 375 standard cubic centimeters per minute.

15. The method of claim 13, wherein the LPCVD process uses boron chloride at a flow rate between about 20 standard cubic centimeters per minute and about 80 standard cubic centimeters per minute.

16. The method of claim 13, wherein the LPCVD process uses phosphene at a flow rate between about 20 standard cubic centimeters per minute and about 80 standard cubic centimeters per minute.

17. The method of claim 13, wherein the LPCVD process is performed at a temperature of between about 450° C. and about 650° C.

18. The method of claim 13, wherein the LPCVD process is performed at a pressure of between about 200 milli-Torr and about 1000 milli-Torr.

19. The method of claim 1, wherein the first conducting layer comprises a thickness of between about 50 angstroms and about 200 angstroms.

20. The method of claim 1, wherein the carbon-based reversible resistance-switching material comprises one or more of amorphous carbon containing nanocrystalline graphene, graphene, graphite, carbon nano-tubes, amorphous diamond-like carbon, silicon carbide and boron carbide.

21. A method of forming a reversible resistance-switching metal-insulator-metal (“MIM”) stack, the method comprising:
forming a first conducting layer comprising a silicide; and
forming a carbon-based reversible resistance-switching material above the first conducting layer;
wherein the first conducting layer and the carbon-based reversible resistance-switching material are formed in the same processing chamber.

22. The method of claim 21, wherein the processing chamber comprises any of a plasma-enhanced chemical vapor deposition chamber, an atomic layer deposition chamber, a thermal chemical vapor deposition chamber and a low pressure chemical vapor deposition chamber.

23. The method of claim 21, wherein forming the first conducting layer comprises:
forming a metal layer; and
thermally reacting the metal layer with a silicon-containing gas to form a metal silicide.

24. The method of claim 23, wherein the metal layer comprises one or more of titanium, tantalum, tungsten and copper.

25. The method of claim 23, wherein the metal comprises a thickness between about 10 angstroms and about 50 angstroms.

26. The method of claim 23, wherein the silicon-containing gas comprises one or more of silane and disilane.

27. The method of claim 23, wherein the thermally reacting step comprises using silicon-containing gas at a flow rate between about 200 standard cubic centimeters per minute and about 500 standard cubic centimeters per minute.

28. The method of claim 23, wherein the thermally reacting step comprises using nitrogen gas at a flow rate between about 1000 standard cubic centimeters per minute and about 10000 standard cubic centimeters per minute.

29. The method of claim 23, wherein the thermally reacting step is performed at a temperature of between about 350° C. and about 550° C.

30. The method of claim 23, wherein the thermally reacting step is performed at a pressure of between about 3 Torr and about 8 Torr.

31. The method of claim 23, wherein the thermally reacting step is performed between about 10 seconds and about 120 seconds.

32. The method of claim 21, wherein the carbon-based reversible resistance-switching material comprises one or more of amorphous carbon containing nanocrystalline graphene, graphene, graphite, carbon nano-tubes, amorphous diamond-like carbon, silicon carbide and boron carbide.

33. A method of forming a memory cell, the method comprising:
forming a first conducting layer comprising a degenerately doped semiconductor material;
forming a carbon-based reversible resistance-switching material above the first conducting layer; and
forming a second conducting layer above the carbon-based reversible resistance-switching material.

34. The method of claim 33, wherein the first conducting layer comprises one or more of silicon, germanium, and a silicon-germanium alloy.

35. The method of claim 33, wherein the first conducting layer comprises one or more of boron, aluminum, gallium, indium, thallium, phosphorous, arsenic, and antimony.

36. The method of claim 33, wherein the first conducting layer has a doping concentration between about 10¹⁸/cm³ and about 10²³/cm³.

37. The method of claim 33, wherein the first conducting layer has a doping concentration between about 10²⁰/cm³ and about 10²³/cm³.

38. The method of claim 33, wherein the first conducting layer is formed by any of plasma-enhanced chemical vapor deposition (“PECVD”), thermal chemical vapor deposition, low pressure chemical vapor deposition (“LPCVD”), physical vapor deposition and atomic layer deposition.

39. The method of claim 33, wherein forming the first conducting layer comprises using a PECVD process using one or more of silane, disilane, boron chloride, diborane, phosphene and helium gasses.

40. The method of claim 39, wherein the PECVD process uses silane at a flow rate between about 10 standard cubic centimeters per minute and about 200 standard cubic centimeters per minute.

41. The method of claim 39, wherein the PECVD process uses diborane at a flow rate between about 10 standard cubic centimeters per minute and about 200 standard cubic centimeters per minute.

42. The method of claim 39, wherein the PECVD process uses phosphene at a flow rate between about 10 standard cubic centimeters per minute and about 200 standard cubic centimeters per minute.

43. The method of claim 39, wherein the PECVD process is performed at a temperature of between about 450° C. and about 600° C.

44. The method of claim 39, wherein the PECVD process is performed at a pressure of between about 3 Torr and about 8 Torr.

45. The method of claim 33, wherein forming the first conducting layer comprises using an LPCVD process using one or more of silane, disilane, boron chloride, diborane, phosphene and helium gasses.

46. The method of claim 45, wherein the LPCVD process uses silane at a flow rate between about 125 standard cubic centimeters per minute and about 375 standard cubic centimeters per minute.

47. The method of claim 45, wherein the LPCVD process uses boron chloride at a flow rate between about 20 standard cubic centimeters per minute and about 80 standard cubic centimeters per minute.

48. The method of claim 45, wherein the LPCVD process uses phosphene at a flow rate between about 20 standard cubic centimeters per minute and about 80 standard cubic centimeters per minute.

49. The method of claim 45, wherein the LPCVD process is performed at a temperature of between about 450° C. and about 650° C.

50. The method of claim 45, wherein the LPCVD process is performed at a pressure of between about 200 milli-Torr and about 1000 milli-Torr.

51. The method of claim 33, wherein the first conducting layer comprises a thickness of between about 50 angstroms and about 200 angstroms.

52. The method of claim 33, wherein the carbon-based reversible resistance-switching material comprises one or more of amorphous carbon containing nanocrystalline graphene, graphene, graphite, carbon nano-tubes, amorphous diamond-like carbon, silicon carbide and boron carbide.

53. The method of claim 33, further comprising forming a steering element coupled to the carbon-based reversible resistance-switching material.

54. The method of claim 53, wherein the steering element comprises a p-n or p-i-n diode.

55. The method of claim 53, wherein the steering element comprises a polycrystalline diode.

56. A memory cell formed according to the method of claim 33.

57. A method of forming a memory cell, the method comprising:
forming a first conducting layer comprising a silicide;
forming a carbon-based reversible resistance-switching material above the first conducting layer, wherein the first conducting layer and the carbon-based reversible resistance-switching material are formed in the same processing chamber; and
forming a second conducting layer above the carbon-based reversible resistance-switching material.

58. The method of claim 57, wherein the processing chamber comprises any of a plasma-enhanced chemical vapor deposition chamber, an atomic layer deposition chamber, a thermal chemical vapor deposition chamber and a low pressure chemical vapor deposition chamber.

59. The method of claim 57, wherein forming the first conducting layer comprises:
forming a metal layer; and
thermally reacting the metal layer with a silicon-containing gas to form a metal silicide.

60. The method of claim 59, wherein the metal layer comprises one or more of titanium, tantalum, tungsten and copper.

61. The method of claim 59, wherein the metal comprises a thickness between about 10 angstroms and about 50 angstroms.

62. The method of claim 59, wherein the silicon-containing gas comprises one or more of silane and disilane.

63. The method of claim 59, wherein the thermally reacting step comprises using silicon-containing gas at a flow rate between about 200 standard cubic centimeters per minute and about 500 standard cubic centimeters per minute.

64. The method of claim 59, wherein the thermally reacting step comprises using nitrogen gas at a flow rate between about 1000 standard cubic centimeters per minute and about 10000 standard cubic centimeters per minute.

65. The method of claim 59, wherein the thermally reacting step is performed at a temperature of between about 350° C. and about 550° C.

66. The method of claim 59, wherein the thermally reacting step is performed at a pressure of between about 3 Torr and about 8 Torr.

67. The method of claim 59, wherein the thermally reacting step is performed between about 10 seconds and about 120 seconds.

68. The method of claim 57, wherein the carbon-based reversible resistance-switching material comprises one or more of amorphous carbon containing nanocrystalline graphene, graphene, graphite, carbon nano-tubes, amorphous diamond-like carbon, silicon carbide and boron carbide.

69. The method of claim 57, further comprising forming a steering element coupled to the carbon-based reversible resistance-switching material.

70. The method of claim 69, wherein the steering element comprises a p-n or p-i-n diode.

71. The method of claim 69, wherein the steering element comprises a polycrystalline diode.

72. A memory cell formed according to the method of claim 57.

73. A memory cell comprising:
a first conducting layer comprising a degenerately doped semiconductor material;
a carbon-based reversible resistance-switching material above the first conducting layer; and
a second conducting layer above the carbon-based reversible resistance-switching material.

74. The memory cell of claim 73, wherein the first conducting layer comprises one or more of silicon, germanium, and a silicon-germanium alloy.

75. The memory cell of claim 73, wherein the first conducting layer comprises one or more of boron, aluminum, gallium, indium, thallium, phosphorous, arsenic, and antimony.

76. The memory cell of claim 73, wherein the first conducting layer has a doping concentration between about 10¹⁸/cm³ and about 10²³/cm³.

77. The memory cell of claim 73, wherein the first conducting layer has a doping concentration between about 10²⁰/cm³ and about 10²³/cm³.

78. The memory cell of claim 73, wherein the first conducting layer is formed by any of plasma-enhanced chemical vapor deposition (“PECVD”), thermal chemical vapor deposition, low pressure chemical vapor deposition (“LPCVD”), physical vapor deposition and atomic layer deposition.

79. The memory cell of claim 73, wherein the first conducting layer is formed using a PECVD process using one or more of silane, disilane, boron chloride, diborane, phosphene and helium gasses.

80. The memory cell of claim 79, wherein the PECVD process uses silane at a flow rate between about 10 standard cubic centimeters per minute and about 200 standard cubic centimeters per minute.

81. The memory cell of claim 79, wherein the PECVD process uses diborane at a flow rate between about 10 standard cubic centimeters per minute and about 200 standard cubic centimeters per minute.

82. The memory cell of claim 79, wherein the PECVD process uses phosphene at a flow rate between about 10 standard cubic centimeters per minute and about 200 standard cubic centimeters per minute.

83. The memory cell of claim 79, wherein the PECVD process is performed at a temperature of between about 450° C. and about 600° C.

84. The memory cell of claim 79, wherein the PECVD process is performed at a pressure of between about 3 Torr and about 8 Torr.

85. The memory cell of claim 73, wherein the first conducting layer is formed using an LPCVD process using one or more of silane, disilane, boron chloride, diborane, phosphene and helium gasses.

86. The memory cell of claim 85, wherein the LPCVD process uses silane at a flow rate between about 125 standard cubic centimeters per minute and about 375 standard cubic centimeters per minute.

87. The memory cell of claim 85, wherein the LPCVD process uses boron chloride at a flow rate between about 20 standard cubic centimeters per minute and about 80 standard cubic centimeters per minute.

88. The memory cell of claim 85, wherein the LPCVD process uses phosphene at a flow rate between about 20 standard cubic centimeters per minute and about 80 standard cubic centimeters per minute.

89. The memory cell of claim 85, wherein the LPCVD process is performed at a temperature of between about 450° C. and about 650° C.

90. The memory cell of claim 85, wherein the LPCVD process is performed at a pressure of between about 200 milli-Torr and about 1000 milli-Torr.

91. The memory cell of claim 73, wherein the first conducting layer comprises a thickness of between about 50 angstroms and about 200 angstroms.

92. The memory cell of claim 73, wherein the carbon-based reversible resistance-switching material comprises one or more of amorphous carbon containing nanocrystalline graphene, graphene, graphite, carbon nano-tubes, amorphous diamond-like carbon, silicon carbide and boron carbide.

93. The memory cell of claim 73, further comprising forming a steering element coupled to the carbon-based reversible resistance-switching material.

94. The memory cell of claim 93, wherein the steering element comprises a p-n or p-i-n diode.

95. The memory cell of claim 93, wherein the steering element comprises a polycrystalline diode.
